(19) United States
(12) Patent Application Publication
(10) Pub. No.: US 2026/0123303 A1
(43) Pub. Date: Apr. 30, 2026

(54) METHODS OF DEPOSITING REFLOWABLE POLYMER FILMS

(71) Applicants: Applied Materials, Inc., Santa Clara, CA (US); National University of Singapore, Singapore (SG)

(72) Inventors: Xinke Wang, Singapore (SG); Rudy James Wojtecki, East Garrison, CA (US); Bekele Worku, San Jose, CA (US); Nasrin Kazem, Santa Clara, CA (US); Wei Shi, Singapore (SG); Vicknesh Sahmuganathan, Singapore (SG); John Sudjono, Singapore (SG); Mark Saly, Santa Clara, CA (US)

(73) Assignees: Applied Materials, Inc., Santa Clara, CA (US); National University of Singapore, Singapore (SG)

(21) Appl. No.: 18/893,051

(22) Filed: Sep. 23, 2024

(51) Int. Cl. H01L 21/02; C23C 16/02; C23C 16/455; C23C 16/56

(52) U.S. Cl. CPC H10P 14/683; C23C 16/02; C23C 16/45553; C23C 16/56; H10P 14/6339; H10P 14/6536

(57) ABSTRACT

Methods of depositing a reflowable polymeric film on a semiconductor substrate are described. Exemplary processing methods may include flowing a first precursor over a semiconductor substrate to form a first portion of polymeric film on the structure. The methods may include removing a first precursor effluent from the semiconductor substrate. A second precursor may then be flowed over the semiconductor substrate to react with the first portion of the polymeric film. The methods may include removing a second precursor effluent from the semiconductor substrate. The methods may include reflowing the polymeric film by exposing the polymeric film to a heat treatment.

### TECHNICAL FIELD

Embodiments of the disclosure relate to semiconductor devices and methods of manufacture. More particularly, embodiments of the disclosure are directed to dry deposition methods for reflowable polymers for semiconductor structures.

### BACKGROUND

Generally, an integrated circuit (IC) refers to a set of electronic devices, e.g., transistors formed on a small chip of semiconductor material, typically silicon. Typically, the IC includes one or more layers of metallization having metal lines to connect the electronic devices of the IC to one another and to external connections. Typically, layers of the interlayer dielectric material are placed between the metallization layers of the IC for insulation.

Semiconductor processing is often guided by ever decreasing node sizes. As dimensions shrink, further challenges arise in many processing steps and structures. This includes interconnect structures, which as a result of reduced node size suffers from resistivity issues and formation issues. At small dimensions (e.g., critical dimensions (CD) under 30 nm), interconnect fills with any kind material are very challenging. This is further complicated for polymeric materials, which are deposited by wet processes, such as spin-coating. Wet processes, however, cannot operate in vacuum environments, and spin-coated polymer materials have a low glass transition temperature (Tg) due to low crystallinity. Accordingly, new methods of depositing reflowable polymeric materials, particularly in 3D structures, are needed.

### SUMMARY

One or more embodiments of the disclosure are directed to methods of depositing films. In one or more embodiments, a method of depositing a reflowable polymeric film comprises: flowing a first precursor over a semiconductor substrate comprising a surface to form a first portion of a polymeric film on the surface, the first precursor comprising a first reactive group; removing a first precursor effluent comprising the first precursor from the semiconductor substrate; flowing a second precursor comprising a second reactive group over the semiconductor substrate to react with the first reactive group to form the polymeric film on the surface; removing a second precursor effluent comprising the second precursor from the semiconductor substrate; and reflowing the polymeric film by exposing the polymeric film to a heat treatment.

Further embodiments of the disclosure are directed to methods of depositing a film. In one or more embodiments, a method of depositing a reflowable polymeric film comprises: performing a process cycle including co-flowing a first precursor and a second precursor over a semiconductor substrate comprising a surface to form a polymeric film on the surface, the first precursor comprising a first reactive group and the second precursor comprising a second reactive group; removing an effluent comprising the first precursor and the second precursor from the semiconductor substrate; co-flowing the first precursor and the second precursor over the semiconductor substrate comprising the surface to form the polymeric film on the surface; removing the effluent comprising the first precursor and the second precursor from the semiconductor substrate; repeating the process cycle x number of times, wherein x is an integer in a range of from 1 to 10000; and reflowing the polymeric film by exposing the polymeric film to a heat treatment.

Additional embodiments of the disclosure are directed to methods of depositing a film. In one or more embodiments, a method of depositing a reflowable polymeric film comprises: co-flowing a first precursor and a second precursor over a semiconductor substrate comprising a surface to form a polymeric film on the surface, the first precursor comprising a first reactive group and the second precursor comprising a second reactive group; and reflowing the polymeric film by exposing the polymeric film to a heat treatment.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2A illustrates a process flow diagram of a method in accordance with one or more embodiments of the disclosure;

FIG. 2B illustrates a process flow diagram of a method in accordance with one or more embodiments of the disclosure;

FIG. 3 illustrates a cross-section view of a substrate in accordance with one or more embodiments of the disclosure; and

FIG. 4 illustrates a cross-section view of a substrate in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In some embodiments, the substrate comprises a rigid discrete material.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

As used in this specification and the appended claims, the terms “reactive compound”, “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to the two or more reactive compounds which are introduced into a reaction zone of a processing chamber.

Polymeric materials may be used in semiconductor device manufacturing for a number of structures and processes, including as a mask material, an etch resistant material, a trench fill material, a photoresist material, and a photoresist underlay material, among other applications. More specific examples of applications for polymeric materials include the formation of hot implant hard masks, metal gate (MG)-cut hard masks, metal gate fabrication, reverse tone patterning, self-aligned patterning, and line width roughness (LWR) reduction, among others.

Typically, polymeric materials are deposited by wet processes, such as spin-coating. Wet processes, however, cannot operate in vacuum environments, and spin-coated polymer materials have a low glass transition temperature (Tg) due to low crystallinity. Accordingly, in one or more embodiments, dry deposition methods are used for reflowable polymers. Dry deposition methods advantageously provided polymeric materials having higher crystallinity, higher molecular weight, higher glass transition temperature (Tg), and better thickness control. The dry deposition methods of one or more embodiments facilitate the use of polymeric materials in a broader range of applications in many different kinds of substrates. For example, in one or more embodiments, reflowable polymeric materials may be used in photoresist patterning, line width reduction (LWR), roughness reduction, self-healing imperfections, and reflow gap fill applications.

In one or more embodiments, molecular layer deposition (MLD) and/or chemical vapor deposition (CVD) are used to deposit reflowable polymers. In one or more embodiments, MLD and/or CVD are used to deposit a polymeric film that can reflow into a new surface topography or shape upon a post-processing, such as, but not limited to, thermal annealing, lithography, focused ion beam, nanoimprinting, and the like.

In specific embodiments, a polymeric film is deposited using molecular layer deposition (MLD), chemical vapor deposition (CVD), or a combination of MLD and CVD. In one or more embodiments, the MLD/CVD methods are dry process in a vacuum chamber at a pressure less than atmospheric pressure. The dry deposition methods of one or more embodiments provide higher crystallinity, higher molecular weight, higher glass transition temperature (Tg), and better thickness control. In one or more embodiments, the glass transition temperature (Tg) can be engineered by choosing different precursors.

The embodiments of the disclosure are described by way of the Figures, which illustrate semiconductor devices (e.g., transistors) and processes for forming semiconductor structures in accordance with one or more embodiments of the disclosure. The processes shown are merely illustrative possible uses for the disclosed processes, and the skilled artisan will recognize that the disclosed processes are not limited to the illustrated applications.

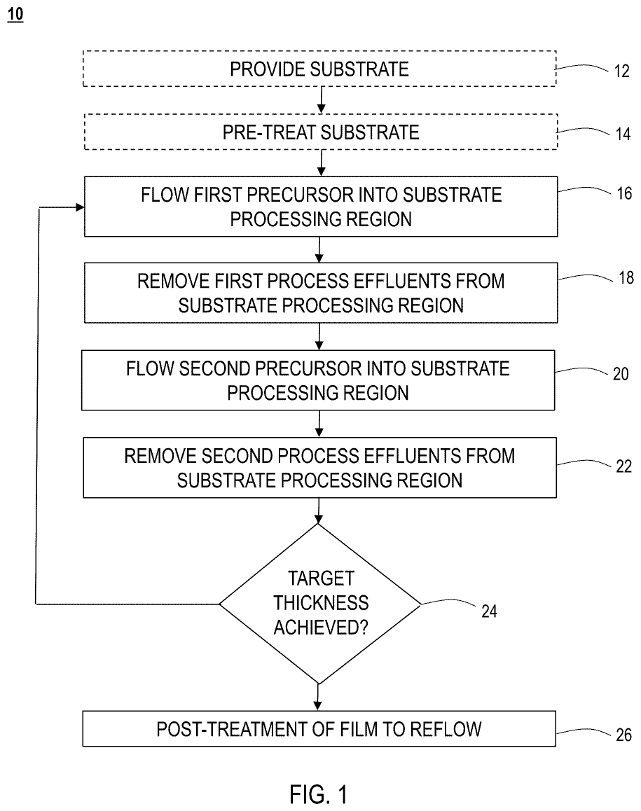

FIG. 1 illustrates a process flow diagram of a method 10 of semiconductor film deposition by molecular layer deposition (MLD) of a reflowable polymeric film according to one or more embodiments.

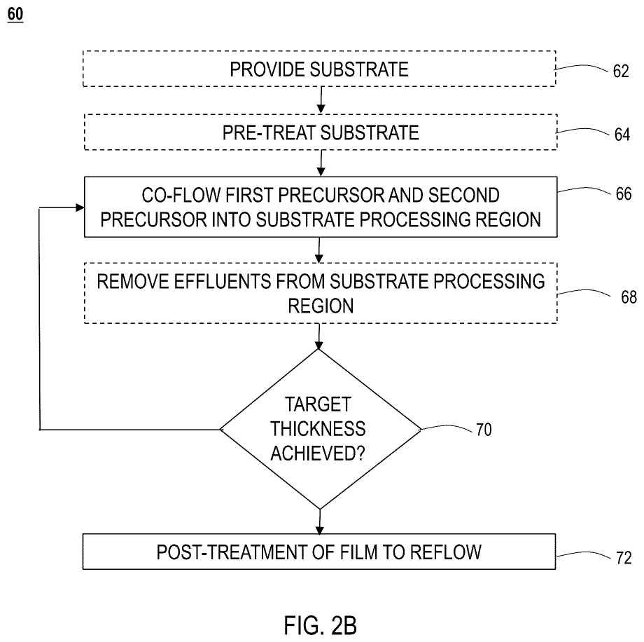

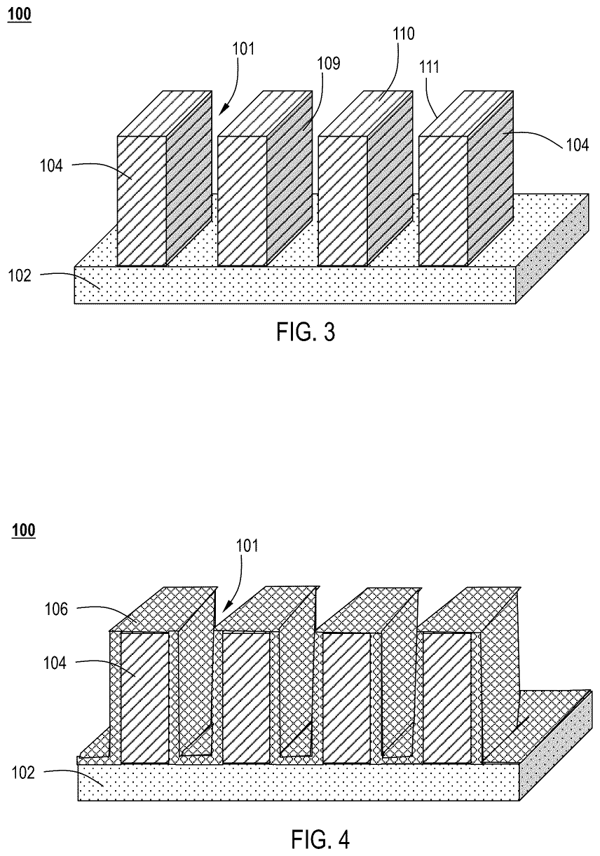

FIGS. 3 and 4 illustrate cross-sectional views of semiconductor substrate being processed according to the method of one or more embodiments. Referring to FIG. 1 and FIGS. 3-4, in one or more embodiments, at operation 10, a semiconductor substrate 102 is provided. As used in this specification and the appended claims, the term “provided” means that the substrate is made available for processing (e.g., positioned in a processing chamber).

Referring to FIG. 3, in one or more embodiments, a semiconductor substrate 102 includes a surface 104. In one or more embodiments, the surface 104 is a surface of one or more 3D semiconductor structure, such as, but not limited to a photoresist, a mandrel, a trench, a via, a hole, and the like.

In one or more embodiments, the surface 104 includes a top surface 110, a first sidewall 109, and a second sidewall 111. In one or more embodiments, the surface 104, may have variation along the line edge (surface irregularities), causing line width roughness (LWR) and line edge roughness (LER). In one or more embodiments, a molecular layer deposition (MLD) polymeric film 106 is coated on the surface 104 so as to smooth the surface to reduce LWR and LER.

As recognized by one of skill in the art, there may be more than one surface 104 on the semiconductor substrate 102. In some embodiments, there are at least two surfaces 104 separated by a feature 101.

In one or more embodiments, the surface 104 on which the polymeric material is formed may include a material in which one or more features 101 may be formed. The features 101 may be characterized by any shape or configuration according to the present technology. In some embodiments, the features 101 may be or include a trench structure, a via structure, or aperture formed within the substrate. Although the features 101 may be characterized by any shapes or sizes, in some embodiments the substrate features 101 may be characterized by higher aspect ratios, or a ratio of a depth of the feature to a width across the feature 101. For example, in some embodiments substrate features may be characterized by aspect ratios greater than or equal to 5:1, and may be characterized by aspect ratios greater than or equal to 10:1, greater than or equal to 15:1, greater than or equal to 20:1, greater than or equal to 25:1, greater than or equal to 30:1, greater than or equal to 40:1, greater than or equal to 50:1, or greater. Additionally, the features 101 may be characterized by narrow widths or diameters across the feature including between two sidewalls, such as a critical dimension in a range of from 5 nm to 500 nm, or in a range of from 10 nm to 200 nm, or in a range of from 20 nm to 100 nm.

In one or more embodiments, the distance, d1, between each of the patterned surfaces 104 is in a range of from 5 nm to 500 nm, or in a range of from 10 nm to 200 nm, or in a range of from 20 nm to 100 nm.

In one or more embodiments, FIGS. 3 and 4 are cross-section views 100 of a semiconductor substrate being processed according to the method of FIG. 1. Referring to FIGS. 1 and 3, in one or more embodiments, at operation 14, the semiconductor substrate 102 and surface 104 may optionally be exposed to a pretreatment process to polish, coat, dope, etch, reduce, oxidize, hydroxylate, anneal, UV cure, e-beam cure and/or bake the substrate. In one or more embodiments, the pre-treatment comprises forming a self-assemble monolayer (SAM) on the semiconductor substrate 102 and on the surface 104. The SAM may comprise any suitable SAM known to the skilled artisan. In one or more embodiments, the SAM comprises 3-aminopropyltrimethoxysilane, ethanolamine, or the like. In one or more embodiments, the pre-treatment operation 34 to form the SAM includes soaking the semiconductor substrate 102 and surface 104 in a gas such as, but not limited to ammonia (NH₃) and/or hydrazine (N₂H₄). In other embodiments, the pre-treatment operation 34 to form a SAM comprises a plasma treatment. The semiconductor substrate 102 and surface 104 may be treated with one or more plasma selected from a nitrogen (N₂) plasma, a hydrogen (H₂) plasma, an argon (Ar) plasma, an ammonia (NH₃) plasma, an oxygen (O₂) plasma, and a helium (He) plasma.

In one or more embodiments, a polymeric film 106 is then formed on the semiconductor substrate 102 and surface 104. In one or more embodiments, deposition of the polymeric film 106 may be substantially conformal. As used herein, a layer which is “substantially conformal” refers to a layer where the thickness is about the same throughout (e.g., on the top, middle and bottom of sidewalls and on the bottom of the feature 101). A layer which is substantially conformal varies in thickness by less than or equal to about 10%, 9%, 8%, 7%, 6%, 5%, 4%, 3%, 2%, 1%, or 0.5%.

With reference to FIG. 1, at operation 16, a first precursor is introduced/flowed into the substrate processing region of a processing chamber and over the substrate surface. The first precursor binds strongly to the semiconductor substrate 102 and surface 104.

In one or more embodiments, the first precursor may be a carbon-containing precursor that has at least two reactive groups that can form a bond with a group attached to the semiconductor substrate 102 and surface 104. Molecules of the first precursor react with the surface groups of the semiconductor substrate 102 and surface 104 to form bonds linking the first precursor molecule to the semiconductor substrate 102 and surface 104. The reactions between the first precursor molecules and the groups on the semiconductor substrate 102 and surface 104 continue until most or all the surface groups are bonded to a reactive group on the first precursor molecules. A first portion of a polymeric film 106 is formed that blocks further reaction between first precursor molecules in the first precursor effluent and the substrate.

The first precursor may comprise any suitable precursor known to the skilled artisan. In one or more embodiments, the first precursor may have a general formula R¹-(X)ₙ wherein n is an integer in a range of from 1 to 6, and R¹ comprises one or more of comprises an alkyl group, an alkenyl group, an aryl or aromatic group, and a cycloalkyl group. In one or more embodiments, (X)ₙ comprises one or more of a hydroxide group, an aldehyde group, a ketone group, an acid group, an amino group, an isocyanate group, a thiocyanate group, and an acyl chloride group.

Unless otherwise indicated, the term “lower alkyl,” “alkyl,” or “alk” as used herein alone or as part of another group includes both straight and branched chain hydrocarbons, containing 1 to 20 carbons, or 1 to 10 carbon atoms, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

Such alkyl groups may optionally include up to 1 to 4 substituents such as halo, for example F, Br, Cl, or I, or CF₃, alkyl, alkoxy, aryl, aryloxy, aryl(aryl) or diaryl, arylalkyl, arylalkyloxy, alkenyl, cycloalkyl, cycloalkylalkyl, cycloalkylalkyloxy, amino, hydroxy, hydroxyalkyl, acyl, heteroaryl, heteroaryloxy, heteroarylalkyl, heteroarylalkoxy, aryloxyalkyl, alkylthio, arylalkylthio, aryloxyaryl, alkylamido, alkanoylamino, arylcarbonylamino, nitro, cyano, thiol, haloalkyl, trihaloalkyl, and/or alkylthio, and the like. In one or more embodiments, R¹ is independently selected from C₁₋₂₀ alkyl. In other embodiments, R¹ is from C₁₋₁₂ alkyl.

As used herein, the term “alkene” or “alkenyl” or “lower alkenyl” refers to straight or branched chain radicals of 2 to 20 carbons, or 2 to 12 carbons, and 1 to 8 carbons in the normal chain, which include one to six double bonds in the normal chain, such as vinyl, 2-propenyl, 3-butenyl, 2-butenyl, 4-pentenyl, 3-pentenyl, 2-hexenyl, 3-hexenyl, 2-heptenyl, 3-heptenyl, 4-heptenyl, 3-octenyl, 3-nonenyl, 4-decenyl, 3-undecenyl, 4-dodecenyl, 4,8,12-tetradecatrienyl, and the like, and which may be optionally substituted with 1 to 4 substituents, namely, halogen, haloalkyl, alkyl, alkoxy, alkenyl, alkynyl, aryl, arylalkyl, cycloalkyl, amino, hydroxy, heteroaryl, cycloheteroalkyl, alkanoylamino, alkylamido, arylcarbonyl-amino, nitro, cyano, thiol, alkylthio, and/or any of the alkyl substituents set out herein.

As used herein, the term “alkynyl” or “lower alkynyl” refers to straight or branched chain radicals of 2 to 20 carbons, or 2 to 12 carbons, or 2 to 8 carbons in the normal chain, which include one triple bond in the normal chain, such as 2-propynyl, 3-butynyl, 2-butynyl, 4-pentynyl, 3-pentynyl, 2-hexynyl, 3-hexynyl, 2-heptynyl, 3-heptynyl, 4-heptynyl, 3-octynyl, 3-nonynyl, 4-decynyl, 3-undecynyl, 4-dodecynyl, and the like, and which may be optionally substituted with 1 to 4 substituents, namely, halogen, haloalkyl, alkyl, alkoxy, alkenyl, alkynyl, aryl, arylalkyl, cycloalkyl, amino, heteroaryl, cycloheteroalkyl, hydroxy, alkanoylamino, alkylamido, arylcarbonylamino, nitro, cyano, thiol, and/or alkylthio, and/or any of the alkyl substituents set out herein.

The term “halogen” or “halo” as used herein alone or as part of another group refers to chlorine, bromine, fluorine, and iodine as well as CF₃.

As used herein, the term “aryl” refers to monocyclic and bicyclic aromatic groups containing 6 to 10 carbons in the ring portion (such as phenyl, biphenyl or naphthyl, including 1-naphthyl and 2-naphthyl) and may optionally include 1 to 3 additional rings fused to a carbocyclic ring or a heterocyclic ring (such as aryl, cycloalkyl, heteroaryl, or cycloheteroalkyl rings). The aryl group may be optionally substituted through available carbon atoms with 1, 2, or 3 substituents, for example, hydrogen, halo, haloalkyl, alkyl, haloalkyl, alkoxy, haloalkoxy, alkenyl, trifluoromethyl, trifluoromethoxy, alkynyl, and the like.

Specific examples of first precursor include, but are not limited to, one or more of terephthaldehyde, terephthaloyl chloride, 1,3,5-benzenetricarbonyl trichloride, hexamethylene chloride, pyromellitic dianhydride, 1,4-phenylene diisocyanate, 4,4′-oxydianiline, and the like.

In one or more embodiments, the formation rate of the first portion of the polymeric film 106 may depend on the temperature of the substrate as well as the temperature of the deposition precursors that flow into the substrate processing region. Exemplary substrate temperatures during the formation operations may be greater than or equal to room temperature, greater than or equal to 50° C., greater than or equal to 60° C., greater than or equal to 70° C., greater than or equal to 80° C., greater than or equal to 90° C., greater than or equal to 100° C., greater than or equal to 110° C., greater than or equal to 120° C., greater than or equal to 130° C., greater than or equal to 140°C., greater than or equal to 150° C., or higher. By maintaining the substrate temperature elevated, such as above or about 100° C. in some embodiments, an increased number of nucleation sites may be available along the semiconductor substrate 102 and patterned surface 104, which may improve formation and reduce void formation by improving coverage at each location. In one or more embodiments, the temperature is at a range of from room temperature to 200° C., or in a range of from 25° C. to 300° C.

The first precursor effluent may remain in the substrate processing region for a period of time to nearly, or completely, form the first portion of the polymeric film 106. The precursors may be delivered in alternating pulses to grow the material. In some embodiments, the pulse times of either or both of the first precursor and the second precursor may be greater than or equal to 0.1 seconds, greater than or equal to 1 second, greater than or equal to 10 seconds, greater than or equal to 100 seconds, greater than or equal to 500 seconds, greater than or equal to 1000 seconds, greater than or equal to 2500 seconds, greater than or equal to 5000 seconds, greater than or equal to 7500 seconds, greater than or equal to 10,000 seconds, or more.

With reference to FIG. 1, at operation 18, the first precursor is purged or removed from the substrate processing region following formation of the first portion of the polymeric film 106. The effluents of the first precursor may be removed by pumping them out of the substrate deposition region for a period of time ranging from 0 seconds to about 10,000 seconds. In some embodiments, however, increased purge time may begin to remove reactive sites, which may reduce uniform formation. Accordingly, in some embodiments the purge may be performed for less than or equal to 10,000 seconds. In some embodiments, a purge gas may be introduced to the substrate processing region to assist in the removal of the effluents. Exemplary purge gases include argon (Ar), helium (He), and nitrogen (N₂), among other purge gases.

Referring to FIG. 1, at operation 20, a second precursor, reacts with the first precursor to form a second portion of polymeric film 106. The second precursor may advantageously have functional groups on one end that increase the thickness of the polymeric film 106.

In one or more embodiments, the second precursor may be a carbon-containing precursor that has at least two reactive groups that can form bonds with unreacted reactive groups of the first precursor that formed the first portion of the polymeric film 106. Molecules of the second precursor react with the unreacted reactive groups of the first precursor to form bonds linking the second precursor molecules to the first precursor molecules. The reactions between the second and first precursor molecules continue until most or all the unreacted reactive groups on the first precursor molecules have reacted with second precursor molecules. A second portion of a polymeric film 106 of the deposition precursors is formed that blocks further reaction between second precursor molecules in the second precursor effluent and the first portion of the polymeric film 106.

The second precursor may comprise any suitable precursor known to the skilled artisan. In one or more embodiments, the second precursor may have a general formula R²-(Y)ₙ wherein n is an integer in a range of from 1 to 6, and R² comprises one or more of an alkyl group, an alkenyl group, an aryl or aromatic group, and a cycloalkyl group. In one or more embodiments, R² is independently selected from C₁₋₂₀ alkyl. In other embodiments, R² is from C₁₋₁₂ alkyl. In one or more embodiments, (Y)ₙ comprises one or more of a hydroxide group, an aldehyde group, a ketone group, an acid group, an amino group, and an acyl chloride group.

Without intending to be bound by theory, it is thought that the second precursor includes a reactive group that can form a covalent bond with a reactive group of the first precursor.

Specific examples of the second precursor include, but are not limited to, one or more of phenylenediamine, ethylenediamine, hexamethylenediamine, tris(2-aminoethyl) amine, ethanolamine, ethylene glycol, and the like.

Referring to FIG. 1, in one or more embodiments, the method 10 also includes an operation 22 to purge or remove the second precursor effluents from the substrate processing region following the formation of the second portion of the polymeric film 106. The effluents may be removed by pumping them out of the substrate deposition region for a period of time ranging from 0 seconds to 10,000 seconds, among other exemplary time ranges. In some embodiments, a purge gas may be introduced to the substrate processing region to assist in the removal of the effluents. Exemplary purge gases include argon, helium, and nitrogen, among other purge gases.

In one or more embodiments, the formation rate of the second portion of the polymeric film 106 may also depend on the pressure of the second precursor effluent in the substrate processing region. Exemplary effluent pressures in the substrate processing region may range from about 1 mTorr to about 20 Torr. Additional exemplary ranges include 5 Torr to 15 Torr, and 9 Torr to 12 Torr, among other exemplary ranges.

With reference to FIG. 1, in one or more embodiments of the method 10 there is a determination/decision point 24 of whether a target thickness of the as-deposited polymeric film 106 on semiconductor substrate 102 and surface 104 has been achieved following one or more cycles of forming a polymeric film 106 (e.g., following the formation of the first and second portions of the film). If a target thickness of as-deposited polymeric film 106 has not been achieved, another cycle of forming first and second portions of a polymeric film 106 is performed. If a target thickness of as-deposited polymeric film 106 has been achieved, another cycle to form another polymeric film 106 is not started. Exemplary numbers of cycles for the formation of polymeric films may include 1 cycle to 2000 cycles. Additional exemplary ranges for the number of cycles may include 50 cycles to 1000 cycles, and 100 cycles to 750 cycles, among other exemplary ranges.

Accordingly, in one or more embodiments, the method 10 further includes depositing at least one additional polymeric film on the initial polymeric film, where the initial polymeric film and the at least one additional polymeric film form the polymeric film 106 on the surface 104 of the substrate 102.

In one or more embodiments, the polymeric film 106 may have any suitable thickness. In one or more embodiments, the thickness of the polymeric film 106 is in a range of from 0.1 nm to 50 nm, or in a range of from 0.1 nm to 200 nm, or in a range of from 1 nm to 20 nm, or in a range of from 1 nm to 10 nm, or in a range of from 3 nm to 10 nm, or in a range of from 1 nm to 5 nm.

In one or more embodiments, the distance, d2, between each of the patterned surfaces 104 after the polymeric film 106 is deposited is in a range of from 5 nm to 500 nm, or in a range of from 10 nm to 200 nm, or in a range of from 20 nm to 100 nm. In one or more embodiments, the distance, d2, between each of the surfaces 104 after the polymeric film 106 is deposited may be less than the distance, d1, between each of the surfaces 104 prior to deposition of the polymeric film 106.

In some embodiments, the polymeric film 106 deposited by the dry deposition method 10 of FIG. 1 has a glass transition temperature (Tg) in a range of from 150° C. to 200° C. Additionally, the polymeric film 106 deposited by the dry deposition method 10 of FIG. 1 results in a polymeric film 106 where surface imperfections and voids are smoothed out upon subsequent reflowing to form a reflowed polymeric film.

In the embodiment shown in method 10 of FIG. 1, the as-deposited polymeric film 106 on the semiconductor substrate 102 and surface 104 is then post-processed at operation 26. The post-processing operation 26 can be any suitable process that results in the reflow of the polymer film 106, such as, but not limited to, thermal annealing, lithography, focused ion beam, nanoimprinting, and the like. As used herein, the term “reflow” refers to a thermal dynamically favored process that involves changing the surface topography or shape of the polymers using energetic particles or heat. When heated above their glass transition temperature, thermoplastic polymers soften and move, which is known as reflow.

In some embodiments, the post-processing operation 26 comprises thermally annealing the polymeric film 106 to cause it to reflow. In some embodiments, thermal annealing is done at temperatures greater than about 100° C., or at about 300° C., 400° C., 500° C., 600° C., 700° C., 800° C., 900° C., or 1000° C., or higher. The thermal annealing environment of some embodiments comprises an inert gas (e.g., molecular nitrogen (N₂), argon (Ar)). Annealing can be performed for any suitable length of time. In some embodiments, the polymeric film is annealed for a predetermined time in the range of about 1 second to about 90 minutes, or in the range of about 1 second to about 60 minutes. In some embodiments, annealing the polymeric film decreases the roughness of the film.

In other embodiments, at operation 26, the polymeric film 106 may be subjected to a lithography process that causes the polymeric film 106 to reflow. In yet further embodiments, at operation 26, the polymeric film may be subjected to a focused ion beam process that causes the polymeric film 106 to reflow. And in still further embodiments, at operation 26, the polymeric film may be subjected to a nanoimprinting process that causes the polymeric film 106 to reflow.

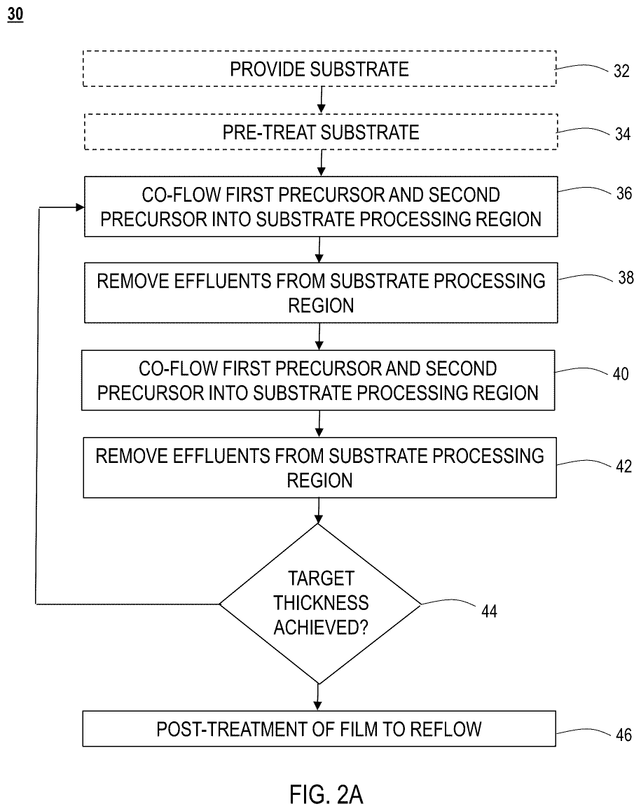

FIG. 2A illustrates a process flow diagram of a method 30 of semiconductor film deposition by a combination of chemical vapor deposition (CVD) and molecular layer deposition (MLD) of a reflowable polymeric film according to one or more embodiments. As discussed above, FIGS. 3 and 4 illustrate cross-sectional views of semiconductor substrate being processed according to the method of one or more embodiments. Referring to FIG. 2A and FIGS. 3-4, in one or more embodiments, at operation 32, a semiconductor substrate 102 is provided. As used in this specification and the appended claims, the term “provided” means that the substrate is made available for processing (e.g., positioned in a processing chamber).

Referring to FIG. 3, in one or more embodiments, a semiconductor substrate 102 includes a surface 104. In one or more embodiments, the surface 104 is a surface of one or more 3D semiconductor structure, such as, but not limited to a photoresist, a mandrel, a trench, a via, a hole, and the like.

In one or more embodiments, the surface 104 includes a top surface 110, a first sidewall 109, and a second sidewall 111. As recognized by one of skill in the art, there may be more than one surface 104 on the semiconductor substrate 102. In some embodiments, there are at least two surfaces 104 separated by a feature 101.

As discussed above, in one or more embodiments, the surface 104 on which the polymeric material is formed may include a material in which one or more features 101 may be formed. The features 101 may be characterized by any shape or configuration according to the present technology. In some embodiments, the features 101 may be or include a trench structure, a via structure, or aperture formed within the substrate.

In one or more embodiments, FIGS. 3 and 4 are cross-section views 100 of a semiconductor substrate being processed according to the method of FIG. 2A. Referring to FIGS. 2A and 3, in one or more embodiments, at operation 34, the semiconductor substrate 102 and surface 104 may optionally be exposed to a pretreatment process to polish, coat, dope, etch, reduce, oxidize, hydroxylate, anneal, UV cure, e-beam cure and/or bake the substrate. In one or more embodiments, the pre-treatment comprises forming a self-assemble monolayer (SAM) on the semiconductor substrate 102 and on the surface 104. The SAM may comprise any suitable SAM known to the skilled artisan. In one or more embodiments, the SAM comprises 3-aminopropyltrimethoxysilane, ethanolamine, or the like. In one or more embodiments, the pre-treatment operation 34 to form the SAM includes soaking the semiconductor substrate 102 and surface 104 in a gas such as, but not limited to ammonia (NH₃) and/or hydrazine (N₂H₄). In other embodiments, the pre-treatment operation 34 to form a SAM comprises a plasma treatment. The semiconductor substrate 102 and surface 104 may be treated with one or more plasma selected from a nitrogen (N₂) plasma, a hydrogen (H₂) plasma, an argon (Ar) plasma, an ammonia (NH₃) plasma, an oxygen (O₂) plasma, and a helium (He) plasma.

In one or more embodiments, a polymeric film 106 is then formed on the semiconductor substrate 102 and surface 104. In one or more embodiments, deposition of the polymeric film 106 may be substantially conformal. As used herein, a layer which is “substantially conformal” refers to a layer where the thickness is about the same throughout (e.g., on the top, middle and bottom of sidewalls and on the bottom of the feature 101). A layer which is substantially conformal varies in thickness by less than or equal to about 10%, 9%, 8%, 7%, 6%, 5%, 4%, 3%, 2%, 1%, or 0.5%.

With reference to FIG. 2A, at operation 36, a first precursor and a second precursor are introduced substantially simultaneously and co-flowed into the substrate processing region of a processing chamber and over the substrate surface.

In one or more embodiments, the first precursor may be a carbon-containing precursor that has at least two reactive groups that can form a bond with a group attached to the semiconductor substrate 102 and surface 104. Molecules of the first precursor react with the surface groups of the semiconductor substrate 102 and surface 104 to form bonds linking the first precursor molecule to the semiconductor substrate 102 and surface 104. The reactions between the first precursor molecules and the groups on the semiconductor substrate 102 and surface 104 continue until most or all the surface groups are bonded to a reactive group on the first precursor molecules. A first portion of a polymeric film 106 is formed that blocks further reaction between first precursor molecules in the first precursor effluent and the substrate.

The first precursor may comprise any suitable precursor known to the skilled artisan. In one or more embodiments, the first precursor may have a general formula R¹-(X)ₙ wherein n is an integer in a range of from 1 to 6, and R¹ comprises one or more of comprises an alkyl group, an alkenyl group, an aryl or aromatic group, and a cycloalkyl group. (X)ₙ comprises one or more of a hydroxide group, an aldehyde group, a ketone group, an acid group, an amino group, an isocyanate group, a thiocyanate group, and an acyl chloride group.

Specific examples of first precursor include, but are not limited to, one or more of terephthaldehyde, terephthaloyl chloride, 1,3,5-benzenetricarbonyl trichloride, hexamethylene chloride, pyromellitic dianhydride, 1,4-phenylene diisocyanate, 4,4′-oxydianiline, and the like.

In one or more embodiments, the second precursor may be a carbon-containing precursor that has at least two reactive groups that can form bonds with unreacted reactive groups of the first precursor that formed the first portion of the polymeric film 106. Molecules of the second precursor react with the unreacted reactive groups of the first precursor to form bonds linking the second precursor molecules to the first precursor molecules. The reactions between the second and first precursor molecules continue until most or all the unreacted reactive groups on the first precursor molecules have reacted with second precursor molecules. A polymeric film 106 of the deposition precursors is formed on the semiconductor substrate 102 and on surface 104.

The second precursor may comprise any suitable precursor known to the skilled artisan. In one or more embodiments, the second precursor may have a general formula R²-(Y)ₙ wherein n is an integer in a range of from 1 to 6, and R² comprises one or more of an alkyl group, an alkenyl group, an aryl or aromatic group, and a cycloalkyl group. In one or more embodiments, R² is independently selected from C₁₋₂₀ alkyl. In other embodiments, R² is from C₁₋₁₂ alkyl. In one or more embodiments, (Y)ₙ comprises one or more of a hydroxide group, an aldehyde group, a ketone group, an acid group, an amino group, and an acyl chloride group.

Without intending to be bound by theory, it is thought that the second precursor includes a reactive group that can form a covalent bond with a reactive group of the first precursor.

Specific examples of the second precursor include, but are not limited to, one or more of phenylenediamine, ethylenediamine, hexamethylenediamine, tris(2-aminoethyl) amine, ethanolamine, ethylene glycol, and the like.

In one or more embodiments, the formation rate of the polymeric film 106 may depend on the temperature of the substrate as well as the temperature of the deposition precursors that flow into the substrate processing region. Exemplary substrate temperatures during the formation operations may be greater than or equal to room temperature, greater than or equal to 50° C., greater than or equal to 60° C., greater than or equal to 70° C., greater than or equal to 80° C., greater than or equal to 90° C., greater than or equal to 100° C., greater than or equal to 110° C., greater than or equal to 120° C., greater than or equal to 130° C., greater than or equal to 140° C., greater than or equal to 150° C., or higher. By maintaining the substrate temperature elevated, such as above or about 100° C. in some embodiments, an increased number of nucleation sites may be available along the semiconductor substrate 102 and patterned surface 104, which may improve formation and reduce void formation by improving coverage at each location. In one or more embodiments, the temperature is at a range of from room temperature to 200° C., or in a range of from 25° C. to 300° C.

The first precursor effluent and the second precursor effluent may remain in the substrate processing region for a period of time to nearly, or completely, form the polymeric film 106. The precursors may be delivered in pulses to grow the material. In some embodiments, the pulse times of both of the first precursor and the second precursor may be greater than or equal to 0.1 seconds, greater than or equal to 1 second, greater than or equal to 10 seconds, greater than or equal to 100 seconds, greater than or equal to 500 seconds, greater than or equal to 1000 seconds, greater than or equal to 2500 seconds, greater than or equal to 5000 seconds, greater than or equal to 7500 seconds, greater than or equal to 10,000 seconds, or more.

With reference to FIG. 2A, at operation 38, the first precursor and the second precursor are purged or removed from the substrate processing region following formation of the polymeric film 106. The effluents of the first precursor and the second precursor may be removed by pumping them out of the substrate deposition region for a period of time ranging from 0 seconds to about 10,000 seconds. In some embodiments, a purge gas may be introduced to the substrate processing region to assist in the removal of the effluents. Exemplary purge gases include argon (Ar), helium (He), and nitrogen (N₂), among other purge gases.

Referring to FIG. 2A, at operation 40, the first precursor and the second precursor are again introduced substantially simultaneously and co-flowed into the substrate processing region of a processing chamber and over the substrate surface. With reference to FIG. 2A, at operation 42, the first precursor and the second precursor are purged or removed from the substrate processing region following formation of the polymeric film 106.

With reference to FIG. 2A, in one or more embodiments of the method 30 there is a determination/decision point 44 of whether a target thickness of the as-deposited polymeric film 106 on semiconductor substrate 102 and surface 104 has been achieved following one or more cycles of forming a polymeric film 106 (e.g., following the formation of the first and second portions of the film). If a target thickness of as-deposited polymeric film 106 has not been achieved, another cycle of forming the polymeric film 106 is performed by introducing the first precursor and the second precursor substantially simultaneously and co-flowing into the substrate processing region of a processing chamber and over the substrate surface. If a target thickness of polymeric film 106 has been achieved, another cycle to form another polymeric film 106 is not started. Exemplary numbers of cycles, x, for the formation of polymeric films may include 1 cycle to 10,000 cycles. Additional exemplary ranges for the number of cycles may include 50 cycles to 1000 cycles, and 100 cycles to 750 cycles, among other exemplary ranges.

In one or more embodiments, the polymeric film 106 may have any suitable thickness. In one or more embodiments, the thickness of the polymeric film 106 is in a range of from 0.1 nm to 50 nm, or in a range of from 0.1 nm to 200 nm, or in a range of from 1 nm to 20 nm, or in a range of from 1 nm to 10 nm, or in a range of from 3 nm to 10 nm, or in a range of from 1 nm to 5 nm.

In some embodiments, the polymeric film 106 deposited by the dry deposition method 30 of FIG. 2A has a glass transition temperature (Tg) in a range of from 150° C. to 200° C. Additionally, the polymeric film 106 deposited by the dry deposition method 30 of FIG. 2A results in a polymeric film 106 where surface imperfections and voids are smoothed out upon subsequent reflowing to form a reflowed polymeric film.

In the embodiment shown in method 30 of FIG. 2A, the as-deposited polymeric film 106 on the semiconductor substrate 102 and surface 104 is then post-processed at operation 46. The post-processing operation 46 can be any suitable process that results in the reflow of the polymer film 106, such as, but not limited to, thermal annealing, lithography, focused ion beam, nanoimprinting, and the like. As used herein, the term “reflow” refers to a thermal dynamically favored process that involves changing the glass transition temperature of polymers using energetic particles or heat. When heated above their glass transition temperature, thermoplastic polymers soften and move, which is known as reflow.

In some embodiments, the post-processing operation 46 comprises thermally annealing the polymeric film 106 to cause it to reflow. In some embodiments, thermal annealing is done at temperatures greater than about 100° C., or at about 300° C., 400° C., 500° C., 600° C., 700° C., 800° C., 900° C., or 1000° C., or higher. The thermal annealing environment of some embodiments comprises an inert gas (e.g., molecular nitrogen (N₂), argon (Ar)). Annealing can be performed for any suitable length of time. In some embodiments, the polymeric film is annealed for a predetermined time in the range of about 1 second to about 90 minutes, or in the range of about 1 second to about 60 minutes. In some embodiments, annealing the polymeric film 106 decreases the roughness of the film and increases the smoothness of the film. In some embodiments, annealing the polymeric film 106 reflows the polymeric film to gap fill the 3D structure.

In other embodiments, at operation 46, the polymeric film 106 may be subjected to a lithography process that causes the polymeric film 106 to reflow. In yet further embodiments, at operation 46, the polymeric film may be subjected to a focused ion beam process that causes the polymeric film 106 to reflow. And in still further embodiments, at operation 46, the polymeric film may be subjected to a nanoimprinting process that causes the polymeric film 106 to reflow.

FIG. 2B illustrates a process flow diagram of a method 60 of semiconductor film deposition by chemical vapor deposition (CVD) of a reflowable polymeric film according to one or more embodiments. As discussed above, FIGS. 3 and 4 illustrate cross-sectional views of semiconductor substrate being processed according to the method of one or more embodiments. Referring to FIG. 2B and FIGS. 3-4, in one or more embodiments, at operation 62, a semiconductor substrate 102 is provided.

Referring to FIG. 3, in one or more embodiments, the semiconductor substrate 102 includes a surface 104. In one or more embodiments, the surface 104 is a surface of one or more 3D semiconductor structure, such as, but not limited to a photoresist, a mandrel, a trench, a via, a hole, and the like.

In one or more embodiments, the surface 104 includes a top surface 110, a first sidewall 109, and a second sidewall 111. As recognized by one of skill in the art, there may be more than one surface 104 on the semiconductor substrate 102. In some embodiments, there are at least two surfaces 104 separated by a feature 101.

As discussed above, in one or more embodiments, the surface 104 on which the polymeric material is formed may include a material in which one or more features 101 may be formed. The features 101 may be characterized by any shape or configuration according to the present technology. In some embodiments, the features 101 may be or include a trench structure, a via structure, or aperture formed within the substrate.

In one or more embodiments, FIGS. 3 and 4 are cross-section views 100 of a semiconductor substrate being processed according to the method of FIG. 2B. Referring to FIGS. 2B and 3, in one or more embodiments, at operation 64, the semiconductor substrate 102 and surface 104 may optionally be exposed to a pretreatment process to polish, coat, dope, etch, reduce, oxidize, hydroxylate, anneal, UV cure, e-beam cure and/or bake the substrate. In one or more embodiments, the pre-treatment comprises forming a self-assemble monolayer (SAM) on the semiconductor substrate 102 and on the surface 104. The SAM may comprise any suitable SAM known to the skilled artisan. In one or more embodiments, the SAM comprises 3-aminopropyltrimethoxysilane, ethanolamine, or the like. In one or more embodiments, the pre-treatment operation 64 to form the SAM includes soaking the semiconductor substrate 102 and surface 104 in a gas such as, but not limited to ammonia (NH₃) and/or hydrazine (N₂H₄). In other embodiments, the pre-treatment operation 64 to form a SAM comprises a plasma treatment. The semiconductor substrate 102 and surface 104 may be treated with one or more plasma selected from a nitrogen (N₂) plasma, a hydrogen (H₂) plasma, an argon (Ar) plasma, an ammonia (NH₃) plasma, an oxygen (O₂) plasma, and a helium (He) plasma.

In one or more embodiments, a polymeric film 106 is then formed on the semiconductor substrate 102 and surface 104. In one or more embodiments, deposition of the polymeric film 106 may be substantially conformal, as described above with respect to FIGS. 1 and 2A.

With reference to FIG. 2B, at operation 66, a first precursor and a second precursor are introduced substantially simultaneously and co-flowed into the substrate processing region of a processing chamber and over the substrate surface.

In one or more embodiments, the first precursor and the second precursor may be any of the first precursors and second precursors described above. Molecules of the first precursor react with the surface groups of the semiconductor substrate 102 and surface 104 to form bonds linking the first precursor molecule to the semiconductor substrate 102 and surface 104. The reactions between the first precursor molecules and the groups on the semiconductor substrate 102 and surface 104 continue until most or all the surface groups are bonded to a reactive group on the first precursor molecules.

In one or more embodiments, the formation rate of the polymeric film 106 may depend on the temperature of the substrate as well as the temperature of the deposition precursors that flow into the substrate processing region. Exemplary substrate temperatures during the formation operations may be greater than or equal to room temperature, greater than or equal to 50° C., greater than or equal to 60° C., greater than or equal to 70° C., greater than or equal to 80° C., greater than or equal to 90° C., greater than or equal to 100° C., greater than or equal to 110° C., greater than or equal to 120° C., greater than or equal to 130° C., greater than or equal to 140° C., greater than or equal to 150° C., or higher. By maintaining the substrate temperature elevated, such as above or about 100° C. in some embodiments, an increased number of nucleation sites may be available along the semiconductor substrate 102 and patterned surface 104, which may improve formation and reduce void formation by improving coverage at each location. In one or more embodiments, the temperature is at a range of from room temperature to 200° C., or in a range of from 25° C. to 300° C.

With reference to FIG. 2B, at operation 68, the first precursor and the second precursor may be optionally purged or removed from the substrate processing region following formation of the polymeric film 106. The effluents of the first precursor and the second precursor may optionally be removed by pumping them out of the substrate deposition region for a period of time ranging from 0 seconds to about 10,000 seconds. In some embodiments, a purge gas may be introduced to the substrate processing region to assist in the removal of the effluents. Exemplary purge gases include argon (Ar), helium (He), and nitrogen (N₂), among other purge gases.

With reference to FIG. 2B, in one or more embodiments of the method 60 there is a determination/decision point 70 of whether a target thickness of the as-deposited polymeric film 106 on semiconductor substrate 102 and surface 104 has been achieved following one or more CVD cycles of forming a polymeric film 106 (e.g., following the formation of the first and second portions of the film). If a target thickness of as-deposited polymeric film 106 has not been achieved, another cycle of forming the polymeric film 106 is performed by introducing the first precursor and the second precursor substantially simultaneously and co-flowing into the substrate processing region of a processing chamber and over the substrate surface. If a target thickness of polymeric film 106 has been achieved, another cycle to form another polymeric film 106 is not started. Exemplary numbers of cycles, x, for the formation of polymeric films may include 1 cycle to 10,000 cycles. Additional exemplary ranges for the number of cycles may include 50 cycles to 1000 cycles, and 100 cycles to 750 cycles, among other exemplary ranges.

In one or more embodiments, the polymeric film 106 may have any suitable thickness. In one or more embodiments, the thickness of the polymeric film 106 is in a range of from 0.1 nm to 50 nm, or in a range of from 0.1 nm to 200 nm, or in a range of from 1 nm to 20 nm, or in a range of from 1 nm to 10 nm, or in a range of from 3 nm to 10 nm, or in a range of from 1 nm to 5 nm.

In some embodiments, the polymeric film 106 deposited by the dry deposition method 60 of FIG. 2B has a glass transition temperature (Tg) in a range of from 150° C. to 200° C. Additionally, the polymeric film 106 deposited by the dry deposition method 60 of FIG. 2B is grown at a high growth rate of about 10 nm/min to 100 nm/min, which results in a polymeric film 106 having a high roughness. In one or more embodiments, subsequent reflowing of the polymeric film 106 to form a reflowed polymeric film smooths out surface imperfections and voids.

In the embodiment shown in method 60 of FIG. 2B, the as-deposited polymeric film 106 on the semiconductor substrate 102 and surface 104 is then post-processed at operation 72. The post-processing operation 72 can be any suitable process that results in the reflow of the polymer film 106, such as, but not limited to, thermal annealing, lithography, focused ion beam, nanoimprinting, and the like. As used herein, the term “reflow” refers to a thermal dynamically favored process that involves changing the glass transition temperature of polymers using energetic particles or heat. When heated above their glass transition temperature, thermoplastic polymers soften and move, which is known as reflow.

In some embodiments, the post-processing operation 72 comprises thermally annealing the polymeric film 106 to cause it to reflow. In some embodiments, thermal annealing is done at temperatures greater than about 100° C., or at about 300° C., 400° C., 500° C., 600° C., 700° C., 800° C., 900° C., or 1000° C., or higher. The thermal annealing environment of some embodiments comprises an inert gas (e.g., molecular nitrogen (N₂), argon (Ar)). Annealing can be performed for any suitable length of time. In some embodiments, the polymeric film is annealed for a predetermined time in the range of about 1 second to about 90 minutes, or in the range of about 1 second to about 60 minutes. In some embodiments, annealing the polymeric film 106 decreases the roughness of the film.

In other embodiments, at operation 72, the polymeric film 106 may be subjected to a lithography process that causes the polymeric film 106 to reflow. In yet further embodiments, at operation 72, the polymeric film may be subjected to a focused ion beam process that causes the polymeric film 106 to reflow. And in still further embodiments, at operation 72, the polymeric film may be subjected to a nanoimprinting process that causes the polymeric film 106 to reflow.

Some embodiments of the disclosure are directed to electronic devices comprising 3D structures having the polymeric film 106 thereon which is then reflowed to fill a gap in the 3D structure.

In some embodiments, the processing region is in a modular system comprising multiple chambers which perform various functions including substrate center-finding and orientation, degassing, annealing, deposition and/or etching. According to one or more embodiments, the modular system includes at least a first processing chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in the processing chamber of modular system, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, the inert gas is used to purge or remove some or all of the reactants (e.g., reactant). According to one or more embodiments, the inert gas is injected at the exit of the processing chamber to prevent reactants (e.g., reactant) from moving from the processing chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into the first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition by minimizing the effect of, for example, local variability in gas flow geometries.

A “pulse” or “dose” as used herein refers to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a reactive gas may vary according to the flow rate of the reactive gas, the temperature of the process gas, the type of control valve, the type of process chamber employed, as well as the ability of the components of the process gas to adsorb onto the substrate. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

Once the polymeric film is deposited, the method may optionally include further processing (e.g., bulk deposition of a dielectric film). In some embodiments, the further processing may be an ALD process.

The disclosure provides that the processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor or controller, transforms the general-purpose computer into a specific purpose computer (controller) that controls the chamber operation such that the processes are performed. The process can be stored on non-transitory computer readable medium including instructions, that, when executed by a controller of a substrate processing chamber, causes the substrate processing chamber to perform the operations of: flow a first precursor over a substrate comprising a patterned surface to form a first portion of a polymeric film on the patterned surface, the first precursor comprising a first reactive group, and the pattern surface comprises a sidewall and a top surface; remove a first precursor effluent comprising the first precursor from the substrate; flow a second precursor comprising a second reactive group over the substrate to react with the first reactive group to form the polymeric film on the patterned surface; remove a second precursor effluent comprising the second precursor from the substrate; and etch the substrate to remove a portion of the polymeric film from a top surface of the patterned surface to form a spacer layer on a first sidewall and on a second sidewall of the patterned surface.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a reflowable polymeric film, the method comprising:
flowing a first precursor over a semiconductor substrate comprising a surface to form a first portion of a polymeric film on the surface, the first precursor comprising a first reactive group;
removing a first precursor effluent comprising the first precursor from the semiconductor substrate;
flowing a second precursor comprising a second reactive group over the semiconductor substrate to react with the first reactive group to form the polymeric film on the surface;
removing a second precursor effluent comprising the second precursor from the semiconductor substrate; and
reflowing the polymeric film by exposing the polymeric film to a heat treatment.

2. The method of claim 1, wherein the first precursor has a general formula R¹-(X)ₙ
wherein R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

3. The method of claim 1, wherein the second precursor has a general formula R²-(Y)ₙ
wherein R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

4. The method of claim 1, wherein the first precursor is independently selected from one or more of terephthaldehyde, terephthaloyl chloride, 1,3,5-benzenetricarbonyl trichloride, hexamethylene chloride, pyromellitic dianhydride, 1,4-phenylene diisocyanate, and 4,4′-oxydianiline, and wherein the second precursor comprises one or more of phenylenediamine, ethylenediamine, hexamethylenediamine, tris(2-aminoethyl)amine, ethanolamine, and ethylene glycol.

5. The method of claim 1, further comprising pre-treating the semiconductor substrate prior to flowing the first precursor, the pre-treating comprising one or more of a gas soaking or a plasma treatment.

6. The method of claim 1, wherein the heat treatment comprises one of more of thermal annealing, lithography, focused ion beam, and nanoimprinting.

7. The method of claim 6, wherein reflowing the polymeric film comprises thermally annealing the polymeric film at a temperature greater than 100° C.

8. The method of claim 1, further comprising repeating the method to form the reflowed polymeric film having a thickness in a range of from 0.1 nm to 50 nm.

9. The method of claim 7, wherein the reflowed polymeric film has a thickness in a range of from 1 nm to 5 nm.

10. A method of depositing a reflowable polymeric film, the method comprising:
performing a process cycle including
co-flowing a first precursor and a second precursor over a semiconductor substrate comprising a surface to form a polymeric film on the surface, the first precursor comprising a first reactive group and the second precursor comprising a second reactive group;
removing an effluent comprising the first precursor and the second precursor from the semiconductor substrate;
co-flowing the first precursor and the second precursor over the semiconductor substrate comprising the surface to form the polymeric film on the surface;
removing the effluent comprising the first precursor and the second precursor from the semiconductor substrate;
repeating the process cycle x number of times, wherein x is an integer in a range of from 1 to 10000; and
reflowing the polymeric film by exposing the polymeric film to a heat treatment.

11. The method of claim 10, wherein the first precursor has a general formula R¹-(X)ₙ
wherein R¹ comprises one or more of an alkyl group, an alkenyl group, an aryl or aromatic group, and a cycloalkyl group, (X)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

12. The method of claim 10, wherein the second precursor has a general formula R²-(Y)ₙ
wherein R² comprises one or more of an alkyl group, an alkenyl group, an aryl or aromatic group, and a cycloalkyl group, (Y)ₙ comprises one or more of a hydroxide group, an aldehyde group, a ketone group, an acid group, an amino group, an isocyanate group, a thiocyanate group, and an acyl chloride group, and n is an integer in a range of from 1 to 6.

13. The method of claim 10, wherein the first precursor is selected from one or more of terephthaldehyde, terephthaloyl chloride, 1,3,5-benzenetricarbonyl trichloride, hexamethylene chloride, pyromellitic dianhydride, 1,4-phenylene diisocyanate, and 4,4′-oxydianiline, and wherein the second precursor comprises one or more of phenylenediamine, ethylenediamine, hexamethylenediamine, tris(2-aminoethyl)amine, ethanolamine, and ethylene glycol.

14. The method of claim 10, further comprising pre-treating the semiconductor substrate prior to co-flowing the first precursor and the second precursor, the pre-treating comprising one or more of a gas soaking or a plasma treatment.

15. The method of claim 10, wherein the heat treatment comprises one of more of thermal annealing, lithography, focused ion beam, and nanoimprinting.

16. The method of claim 15, wherein reflowing the polymeric film comprises thermally annealing the polymeric film at a temperature greater than 100° C.

17. The method of claim 10, wherein the reflowed polymeric film has a thickness in a range of from 0.1 nm to 50 nm.

18. A method of depositing a reflowable polymeric film, the method comprising:
co-flowing a first precursor and a second precursor over a semiconductor substrate comprising a surface to form a polymeric film on the surface, the first precursor comprising a first reactive group and the second precursor comprising a second reactive group; and
reflowing the polymeric film by exposing the polymeric film to a heat treatment.

19. The method of claim 18, wherein the heat treatment comprises thermally annealing the polymeric film at a temperature greater than 100° C.

20. The method of claim 18, wherein the first precursor is selected from one or more of terephthaldehyde, terephthaloyl chloride, 1,3,5-benzenetricarbonyl trichloride, hexamethylene chloride, pyromellitic dianhydride, 1,4-phenylene diisocyanate, and 4,4′-oxydianiline, and wherein the second precursor comprises one or more of phenylenediamine, ethylenediamine, hexamethylenediamine, tris(2-aminoethyl)amine, ethanolamine, and ethylene glycol.
